(19) United States
(12) Patent Application Publication
(10) Pub. No.: US 2026/0040576 A1
(43) Pub. Date: Feb. 5, 2026

(54) MEMORY CELL FORMATION IN PIER & PILLAR ARCHITECTURE

(71) Applicant: Micron Technology, Inc., Boise, ID (US)

(72) Inventors: Lorenzo Fratin, Buccinasco (MI) (IT); Fabio Pellizzer, Boise, ID (US); Zhao Zhao, Meridian, ID (US); Enrico Varesi, Milano (MI) (IT); Matthew Thorum, Boise, ID (US); Stephen W. Russell, Boise, ID (US); Nirav Vora, Meridian, ID (US)

(21) Appl. No.: 19/271,644

(22) Filed: Jul. 16, 2025

Related U.S. Application Data
(60) Provisional application No. 63/677,330, filed on Jul. 30, 2024.

(51) Int. Cl. H10B 63/00

(52) U.S. Cl. CPC H10B 63/24

(57) ABSTRACT

Methods, systems, and devices for memory cell formation in pier and pillar architectures are described. A stack of materials including alternating layers of nitride and oxide may be formed, and a plurality of columns of a third material may be formed in the stack. The third material may be recessed (e.g., laterally) filled with at least an electrode liner and a metal material. Portions of the nitride material and an oxide liner that are adjacent to the third material may be removed, and a second electrode liner may be formed (e.g., in the regions from which the nitride material and oxide liner were removed). Memory cells may be formed after removing the portion of the nitride material and oxide liner such that the cells are in contact with the second electrode liner.

### CROSS REFERENCE

The present application for patent claims the benefit of U.S. Provisional Patent Application No. 63/677,330 by FRATIN et al., entitled “MEMORY CELL FORMATION IN PIER & PILLAR ARCHITECTURE,” filed Jul. 30, 2024, assigned to the assignee hereof, and expressly incorporated by reference herein.

### TECHNICAL FIELD

The following relates to one or more systems for memory, including memory cell formation in pier and pillar architecture.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory array that supports memory cell formation in pier and pillar architecture in accordance with examples as disclosed herein.

FIG. 2 shows a top view of an example of a memory array that supports memory cell formation in pier and pillar architecture in accordance with examples as disclosed herein.

FIGS. 3A and 3B show side views of an example of a memory array that supports memory cell formation in pier and pillar architecture in accordance with examples as disclosed herein.

FIGS. 4A through 4N show manufacturing steps that support memory cell formation in pier and pillar architecture in accordance with examples as disclosed herein.

FIG. 5A through 5M show manufacturing steps that support memory cell formation in pier and pillar architecture in accordance with examples as disclosed herein.

FIG. 6 shows a flowchart illustrating a method or methods that support memory cell formation in pier and pillar architecture in accordance with examples as disclosed herein.

### DETAILED DESCRIPTION

In some semiconductor manufacturing processes, memory cells may be formed within a memory architecture based on performing a series of processing steps. For example, after a stack of materials including alternating layers of nitride and oxide are formed, piers may be formed through the stack of materials to provide mechanical support for subsequent processing steps, as well as access to the layers for some processing steps such as replacing layers with a different material. Next, cavities for pillars may be formed through the stack of materials, and the layers of nitride may be replaced (e.g., metalized) with a metal to form access lines (e.g., word lines). Then, electrodes may be formed in the cavities and etched back to provide space for the pillars and the memory cells. The pillars may be formed within the cavities and the memory cells may be formed between the pillars and the electrodes.

Such memory architectures may have a relatively high density. That is, such memory architectures may include a relatively large quantity of memory cells located within a relatively small area. However, as the demand for high performance storage devices increases, a demand for higher-density architectures also increases. Such higher-density architectures may include, for example, multiple (e.g., four) memory cells per word line layer formed via each of the cavities for forming the pillars. However, manufacturing such devices may provide various fabrication challenges, including a relatively large quantity of processing steps, high costs, or both.

In accordance with examples as described herein, a memory architecture may have multiple (e.g., four) memory cells per word line layer per pillar opening, which may increase the density of the associated memory device by including multiple (e.g., two) pillars in each pillar opening, while utilizing a reduced or otherwise streamlined quantity of manufacturing steps relative to conventional approaches, is described herein. For example, after a stack of materials including alternating layers of nitride and oxide are formed, a plurality of columns (e.g., of a sacrificial material) and a plurality of vertical cavities are formed in the stack of materials. The layers of nitride (e.g., of the stack of materials) may be replaced (e.g., metalized) with a metal to form access lines (e.g., word lines), and portions of the columns may be removed to form lateral recesses on both sides of the columns. By recessing both sides of the columns, the resulting architecture may include two pillars per pillar opening, which may increase the density of the associated memory system.

An electrode liner may be formed in the lateral recesses and one or more materials may be formed inside the liner (e.g., within the lateral recesses). A portion of the electrode liner may be removed such that regions adjacent to the columns are exposed. For example, a portion of the electrode liner may remain in vertical cavities used for pillar formation, and a portion of the electrode liner that is adjacent to the columns may be removed. By removing the electrode liner from areas adjacent to the columns, material (e.g., a liner and a nitride) may be etched back to support memory cell formation therein. An electrode liner may be formed in the resulting cavities before a memory cell material is deposited (e.g., to form memory cells in contact with the pillars). Accordingly, the resulting architecture may support two pillars per pillar formation, and each pillar formation may include multiple (e.g., four) memory cells per word line layer, which may increase the overall density of the associated memory device while utilizing a reduced or otherwise streamlined quantity of manufacturing steps relative to conventional approaches.

In addition to applicability in memory systems as described herein, techniques for memory cell formation for pier and pillar architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by forming multiple memory cells per pillar, which may improve the overall density of the associated memory device, among other benefits.

Features of the disclosure are illustrated and described in the context of memory devices and arrays. Features of the disclosure are further illustrated and described in the context of memory architectures, manufacturing processes, and flowcharts.

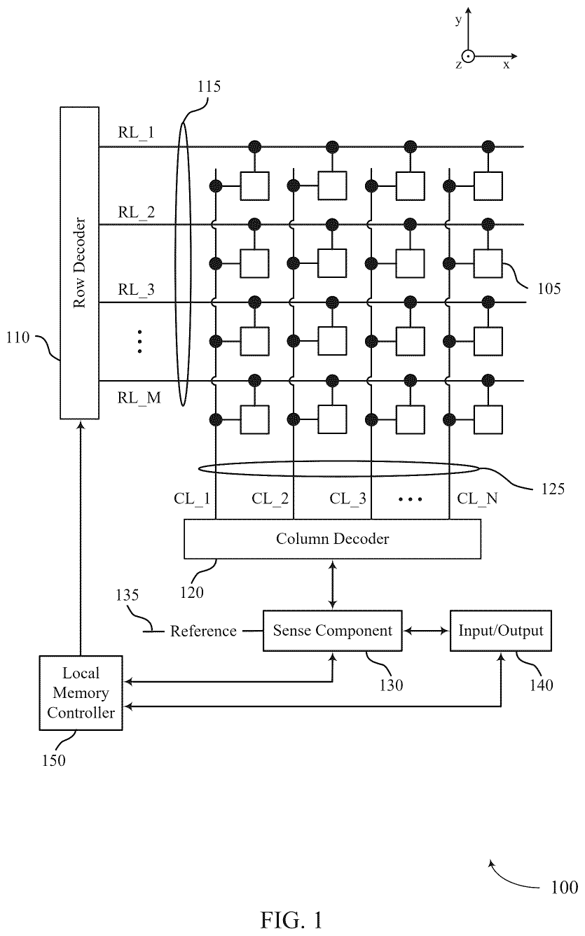

FIG. 1 shows an example of a memory device 100 that supports memory cell formation in pier and pillar architecture in accordance with examples as disclosed herein. In some examples, the memory device 100 may be referred to as or include a memory die, a memory chip, or an electronic memory apparatus. The memory device 100 may be operable to provide locations to store information (e.g., physical memory addresses) that may be used by a system (e.g., a host device coupled with the memory device 100, for writing information, for reading information).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 105, for self-selecting memory cells 105), some or all of the set of logic states supported by the memory cells 105 may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting or thresholding memory cell 105 may have a high threshold voltage state and a low threshold voltage state, where a corresponding “threshold voltage” may refer to a voltage at which or above which the memory cell 105 transitions from a relatively higher-resistance (e.g., non-conductive) state to a relatively lower-resistance (e.g., conductive) state, such as in response to an applied voltage. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics (e.g., resistivity characteristics, conductivity characteristics) of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

In accordance with examples as described herein, a memory architecture having multiple (e.g., four) memory cells 105 formed per word line layer per pillar opening, while utilizing a reduced or otherwise streamlined quantity of manufacturing steps relative to conventional approaches, is described herein. For example, after a stack of materials including alternating layers of nitride and oxide are formed, a plurality of columns (e.g., of a material) and a plurality of vertical cavities are formed in the stack of materials. The layers of nitride (e.g., of the stack of materials) may be replaced (e.g., metalized) with a metal to form access lines (e.g., word lines), and portions of the columns may be removed to form lateral recesses. An electrode liner may be formed in the lateral recesses and one or more materials may be formed inside the liner (e.g., within the lateral recesses). A portion of the electrode liner may be removed such that regions adjacent to the columns are exposed. The regions may be etched and an electrode liner may be formed therein before a memory cell material is deposited (e.g., to form memory cells 105 in contact with the pillars). Accordingly, each pillar opening may include multiple (e.g., two) pillars, which may increase the overall density of the associated memory device while utilizing a reduced or otherwise streamlined quantity of manufacturing steps relative to conventional approaches.

The memory device 100 may include any quantity of non-transitory computer readable media that support memory cell formation in pier and pillar architecture. For example, a local memory controller 150, a row decoder 110, a column decoder 120, a sense component 130, or an input/output component 140, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

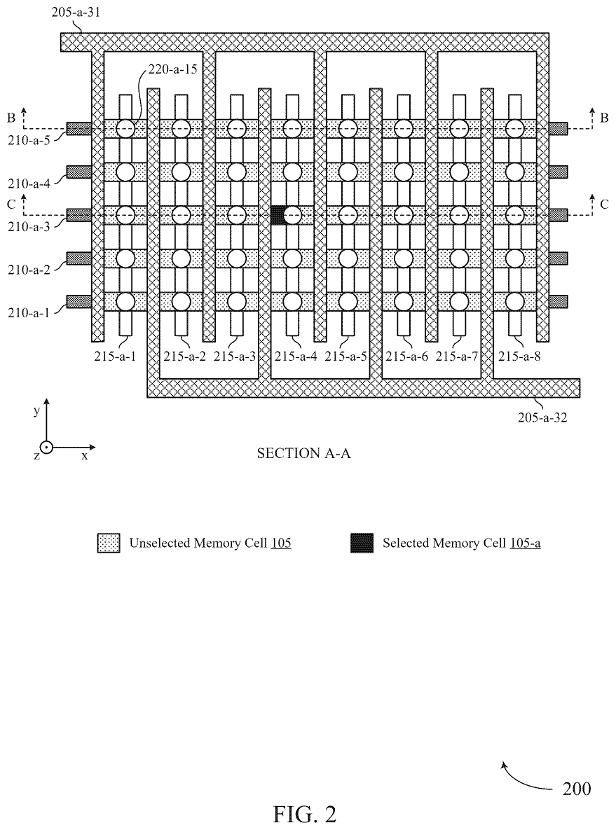

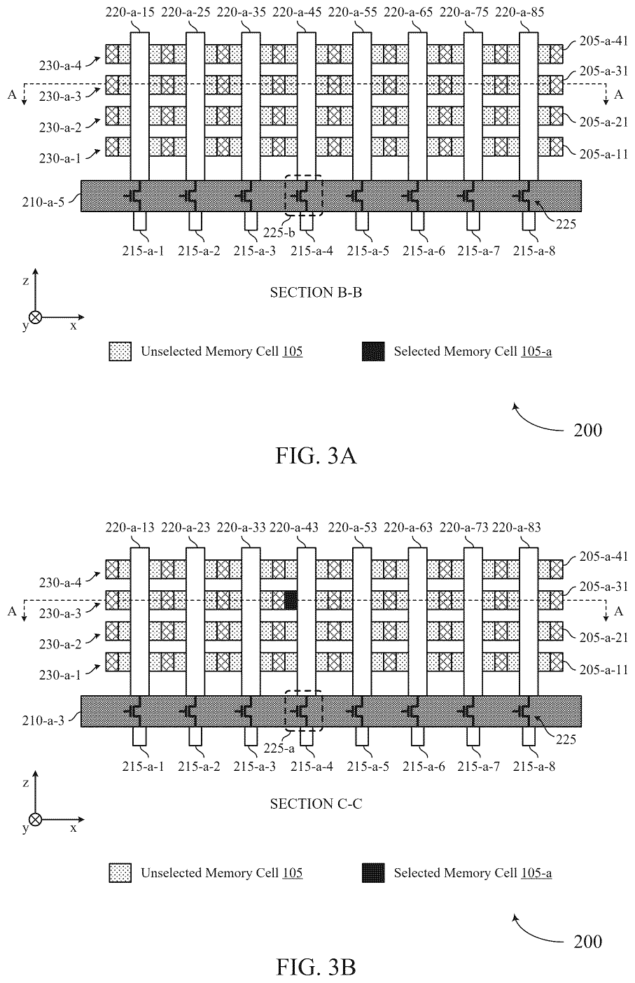

FIGS. 2, 3A, and 3B show an example of a memory array 200 that supports memory cell formation in pier and pillar architecture in accordance with examples as disclosed herein. The memory array 200 may be included in a memory device 100, and illustrates an example of a three-dimensional arrangement of memory cells 105 that may be accessed by various conductive structures (e.g., access lines). FIG. 2 illustrates a top section view (e.g., SECTION A-A) of the memory array 200 relative to a cut plane A-A as shown in FIGS. 3A and 3B. FIG. 3A illustrates a side section view (e.g., SECTION B-B) of the memory array 200 relative to a cut plane B-B as shown in FIG. 2. FIG. 3B illustrates a side section view (e.g., SECTION C-C) of the memory array 200 relative to a cut plane C-C as shown in FIG. 2. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2, 3A, and 3B. Although some elements included in FIGS. 2, 3A, and 3B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers, as illustrated in FIGS. 3A and 3B). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 3A, may be biased with a voltage equal to or similar to an access bias (e.g., −V_{access}/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=V_{read}, which may be a positive voltage or a negative voltage) across the memory cell 105. In some examples, a logic state of the memory cell 105 may be evaluated based on whether the memory cell 105 thresholds (e.g., transitions to a relatively lower-resistance or conductive state, permits current) in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

In accordance with examples as described herein, a memory architecture having multiple (e.g., two) pillars per pillar opening, which may increase the density of the associated memory device, while utilizing a reduced or otherwise streamlined quantity of manufacturing steps relative to conventional approaches, is described herein. For example, after a stack of materials including alternating layers of nitride and oxide are formed, a plurality of columns (e.g., of a sacrificial material within respective pillar openings) and a plurality of vertical cavities are formed in the stack of materials. The layers of nitride (e.g., of the stack of materials) may be replaced (e.g., metalized) with a metal to form access lines (e.g., word lines 205), and portions of the columns may be removed to form lateral recesses on both sides of the columns. By recessing both sides of the columns, the resulting architecture may include two pillars per pillar opening, which may increase the density of the associated memory system.

An electrode liner may be formed in the lateral recesses and one or more materials may be formed inside the liner (e.g., within the lateral recesses). A portion of the electrode liner may be removed such that regions adjacent to the columns are exposed. For example, a portion of the electrode liner may remain in vertical cavities used for pillar formation, and a portion of the electrode liner that is adjacent to the columns may be removed. By removing the electrode liner from areas adjacent to the columns, material (e.g., a liner and a nitride) may be etched back to support memory cell formation therein. An electrode liner may be formed in the resulting cavities before a memory cell material is deposited (e.g., to form memory cells 105 in contact with the pillars). Accordingly, the resulting architecture may support two pillars formed within each pillar opening, and each pillar may be coupled with multiple (e.g., two) memory cells 105 per word line 205 layer, which may increase the overall density of the associated memory device while utilizing a reduced or otherwise streamlined quantity of manufacturing steps relative to conventional approaches.

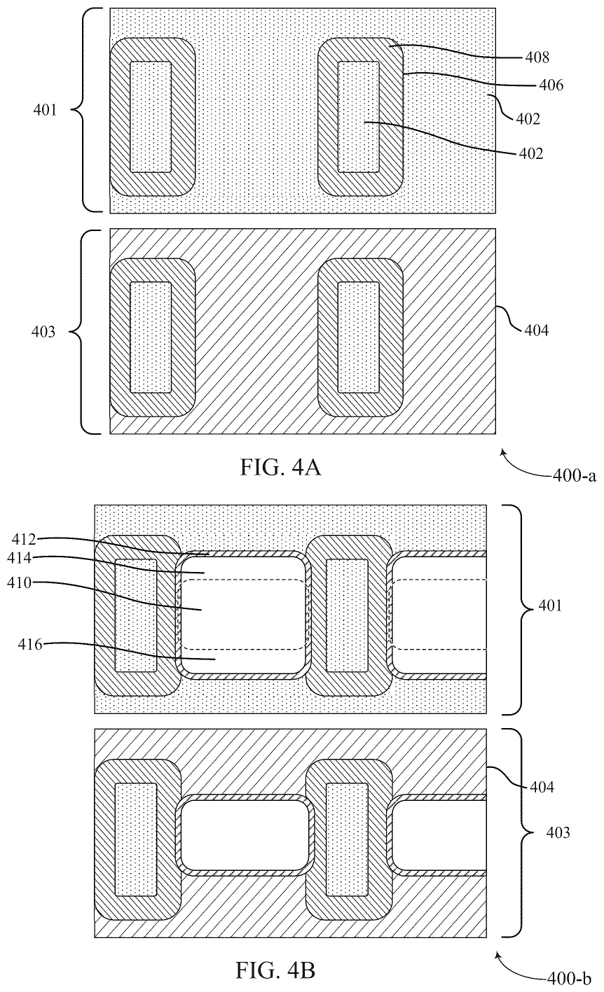

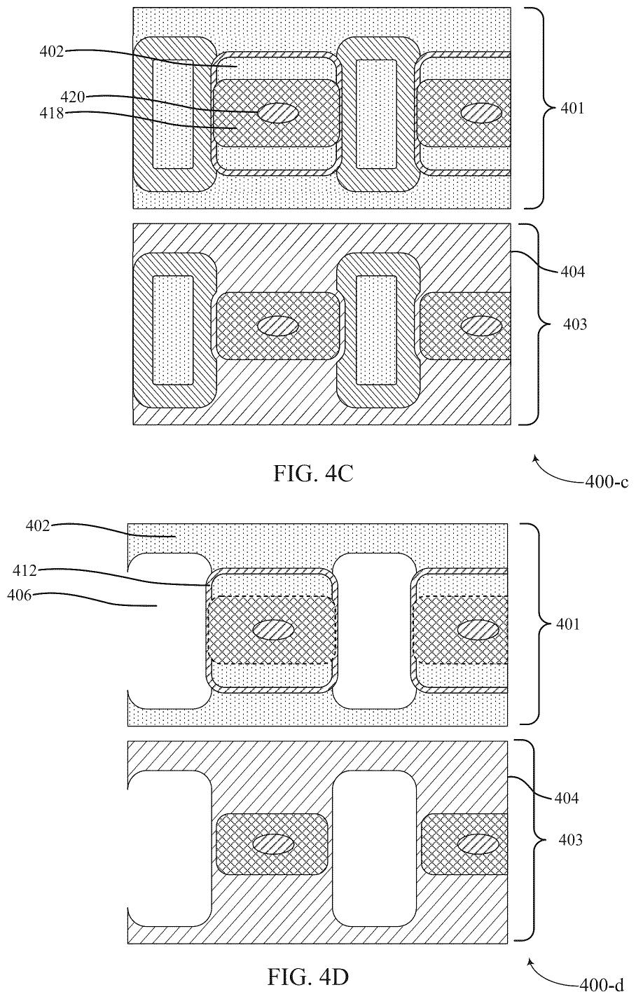

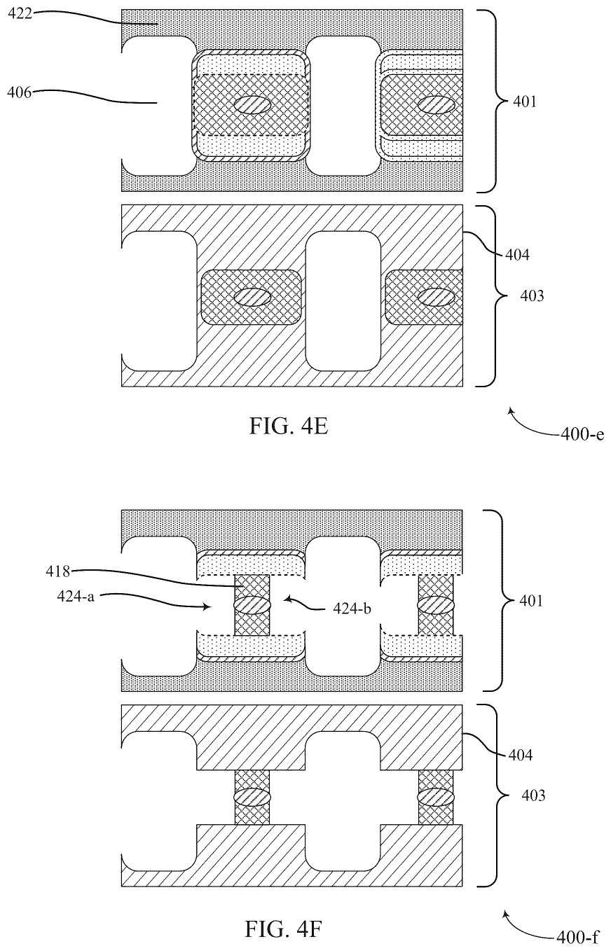

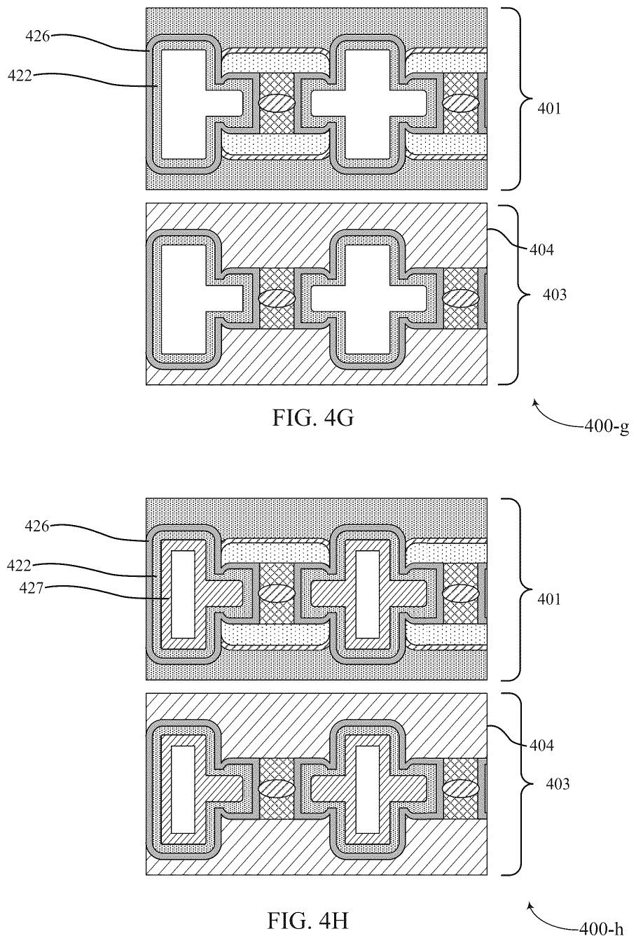

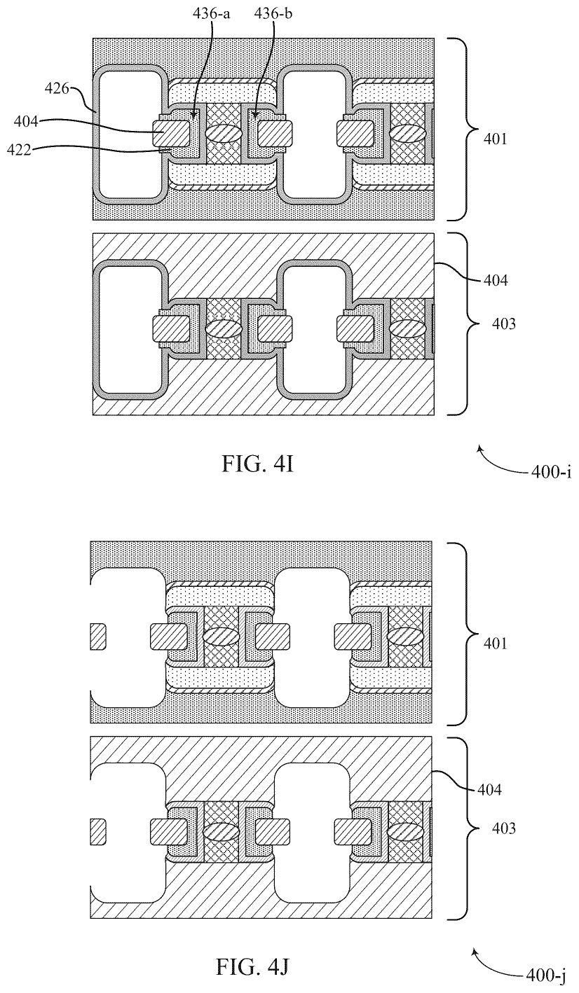

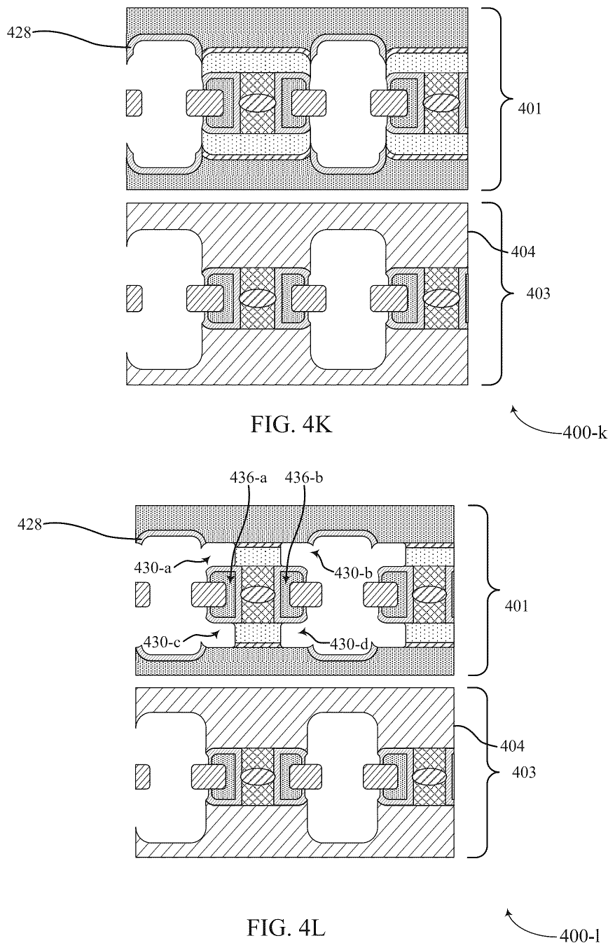

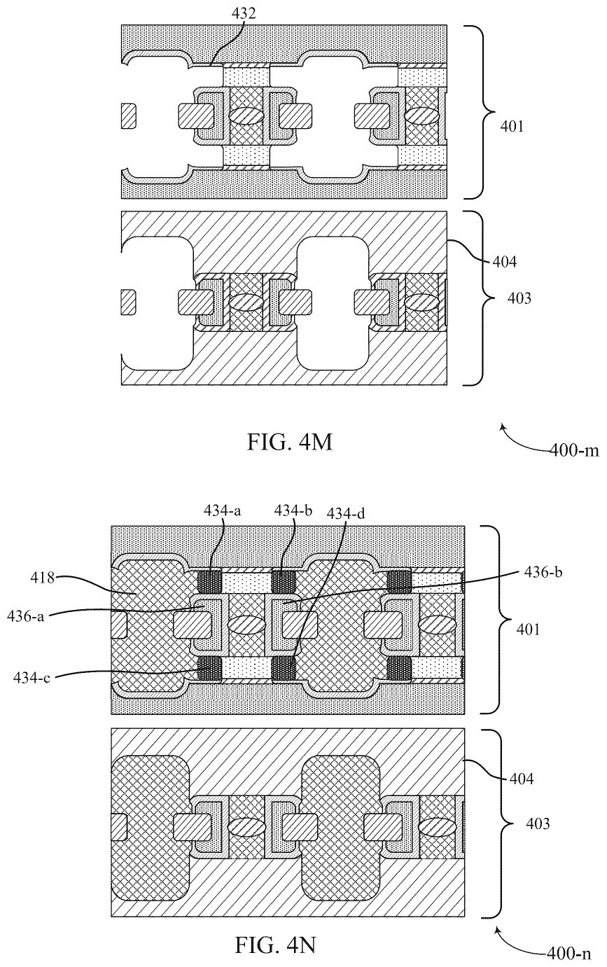

FIG. 4A shows an example of a top-down view of a memory architecture 400-a that supports memory cell formation in pier and pillar architecture in accordance with examples as disclosed herein. FIG. 4A may illustrate one or more vertical cavities 406 being formed in a stack of materials, which may support forming multiple memory cells per pillar using a reduced or otherwise streamlined quantity of manufacturing steps as described herein.

In some instances, the memory architecture 400-a may illustrate a first layer 401 of a stack of materials and a second layer 403 of the stack of materials. For example, the first layer 401 may include a first material 402 and the second layer 403 may include a second material 404. In some instances, the first material 402 may be a nitride material and the second material 404 may be an oxide material. The stack of materials may include alternating layers of the first layer 401 and the second layer 403, which may have been deposited in a prior manufacturing step. The stack of materials may include any quantity of layers.

In some instances, one or more vertical cavities 406 may have been formed through the stack of materials in a prior manufacturing step. The vertical cavities 406 may be formed to support pier formation during a later manufacturing step, and may be formed through the layers including the first material 402 and the layers including the second material 404. For example, each vertical cavity 406 may represent a location in the stack of materials in which a pier is formed. In some examples, each vertical cavity 406 may include the first material 402 (e.g., a nitride material) that is surrounded by a liner 408. In some instances, the liner 408 may include a silicon carbonitride, a carbon-doped material, or a boron-doped material. The first material 402 and the liner 408 formed within the vertical cavities 406 may be sacrificial materials, meaning that they may be removed partially or entirely during one or more subsequent manufacturing steps.

FIG. 4B shows an example of a top-down view of a memory architecture 400-b that supports memory cell formation in pier and pillar architecture in accordance with examples as disclosed herein. FIG. 4B may illustrate one or more cavities 410 being formed between each vertical cavity 406, which may support forming multiple pillars per pillar opening using a reduced or otherwise streamlined quantity of manufacturing steps as described herein.

In some instances, the memory architecture 400-b may illustrate one or more cavities 410 formed between each vertical cavity 406. In some instances, each cavity 410 may be referred to as a third cavity or as a pillar opening. The cavities 410 may be formed in the stack of materials using an etching process, such as wet etching process or a dry etching process. The cavities 410 may be formed to support pillar formation during a later manufacturing step, and may be formed through the layers 401 including the first material 402 and the layers 403 including the second material 404. In some instances, a liner 412 may be formed in each cavity 410. The liner 412 may be a dielectric material (e.g., an oxide material) and may be deposited to protect materials deposited within each cavity 410 during later manufacturing steps. The liner 412 may be formed at the layers including the first material 402 and the layers including the second material 404.

In some instances, the cavities 410 may be adjacent to one or more regions to be filled with a material during a later manufacturing step. For example, each cavity 410 may be adjacent to a first region 414 and a second region 416. In some instances, the first layer 401 may be recessed by etching through the cavities 410 (e.g., using a different etch than used to form the cavities 410). The first region 414 and the second region 416 may eventually be filled with the first material 402 (e.g., a portion of the liner 412 of the first region 414 may partially surround the first material 402 deposited in the cavity 410, a portion of the liner 412 of the second region 416 may partially surround the first material 402 deposited in the cavity 410). The first region 414 and the second region 416 may surround the cavities 410 in which a polysilicon material, hafnium oxide, silicon oxide, or a combination thereof may be deposited during a later manufacturing step.

In some instances, the first region 414 and the second region 416 may exist in the stack of materials at the first layers 401. For example, the plurality of cavities 410 may extend through layers of the first material 402 and layers of the second material 404, and recesses may be formed (e.g., at the first layer 401) into the first material 402 at the first region 414 and the second region 416. The recesses may be formed into the first region 414 and the second region 416 using a selective etching process, which may utilize a wet etching process or a dry etching process.

FIG. 4C shows an example of a top-down view of a memory architecture 400-c that supports memory cell formation in pier and pillar architecture in accordance with examples as disclosed herein. FIG. 4C may illustrate one or more cavities 410 being filled with a third material 418 (e.g., to form a column of third material 418), which may support forming multiple pillars per pillar opening using a reduced or otherwise streamlined quantity of manufacturing steps as described herein.

In some instances, third material 418 may be deposited in each cavity 410. The third material 418 may be a dielectric or seal material (e.g., polysilicon material, hafnium oxide, silicon oxide, or a combination thereof). Additionally, or alternatively, the third material 418 may be deposited such that an opening 420 exists in the third material 418. The opening may be filled by the second material 404. In some examples, the opening 420 may be formed by selectively etching the third material 418. Filing the opening 420 with the second material 404 may prevent the opening 420 from undesirable results (e.g., blowing up) during a later manufacturing step (e.g., when recessing the third material 418 through the vertical cavity 406). Further, the first material 402 may be deposited in each of the first region 414 and the second region 416 such that a portion of the first material 402 is adjacent to the third material 418 and the liner 412.

FIG. 4D shows an example of a top-down view of a memory architecture 400-d that supports memory cell formation in pier and pillar architecture in accordance with examples as disclosed herein. FIG. 4D may illustrate the materials from each vertical cavity 406 being exhumed (e.g., etched, removed), which may support forming multiple pillars per pillar opening using a reduced or otherwise streamlined quantity of manufacturing steps as described herein.

In some instances, the first material 402 and the liner 408 may be removed from each vertical cavity 406 (e.g., at layers of the first material 402 and layers of the second material 404). In some examples, the first material 402 and the liner 408 may be removed using a wet etching process or a dry etching process. The first material 402 and the liner 408 may be removed such that each vertical cavity does not include any materials, and such that a portion of the liner 412 is exposed.

FIG. 4E shows an example of a top-down view of a memory architecture 400-e that supports memory cell formation in pier and pillar architecture in accordance with examples as disclosed herein. FIG. 4E may illustrate a metallization process performed at layers of the stack that formerly included the first material 402, which may support forming multiple pillars per pillar opening using a reduced or otherwise streamlined quantity of manufacturing steps as described herein.

In some instances, FIG. 4E may illustrate a replacement gate (RG) process where layers of the first material 402 at the first layers 401 of the stack of materials are replaced with a fourth material 422. For example, the RG process may be performed via the vertical cavities 406. In some instances the fourth material 422 may be a conductive material (e.g., metallic material), such as tungsten (W), and the RG process may support the formation of word lines in the stack of materials. As shown in FIG. 4E, the RG process may not occur at the second layers 403 of the second material 404.

FIG. 4F shows an example of a top-down view of a memory architecture 400-f that supports memory cell formation in pier and pillar architecture in accordance with examples as disclosed herein. FIG. 4F may illustrate portions of the third material 418 (e.g., a portion of the columns of the third material 418) being removed, which may support forming multiple pillars per pillar opening using a reduced or otherwise streamlined quantity of manufacturing steps as described herein.

In some instances, a portion of the columns of the third material 418 may be removed to form lateral recesses 424 in the columns of the third material 418. A portion of the liner 412 may also be removed. For example, a selective etching process may be performed at the layers of the first material 402 and the layers of the second material 404. In some instances, the liner 412 and the third material 418 may be removed during a same etching process (e.g., a single etching process) or during different etching processes (e.g., multiple etching processes), and may utilize a same or a different etchant or etching process.

The selective etching process may be performed using a wet etching process or a dry etching process and may form a respective first lateral recess 424-a and a second lateral recess 424-b in each column of the third material 418. The etching process may remove a portion of the liner 412 and a portion of the third material 418 such that the first material 402 of the first region 414 and the first material 402 of the second region 416 is adjacent to the respective lateral recesses 424.

FIG. 4G shows an example of a top-down view of a memory architecture 400-g that supports memory cell formation in pier and pillar architecture in accordance with examples as disclosed herein. FIG. 4G may illustrate a liner 426 (e.g., an electrode liner, a first electrode liner) and the fourth material 422 being formed (e.g., deposited) in each lateral recess 424 and vertical cavity 406, which may support forming multiple pillars per pillar opening using a reduced or otherwise streamlined quantity of manufacturing steps as described herein.

In some instances, the liner 426 may extend around a perimeter of each lateral recess 424 and around the perimeter of each vertical cavity 406. For example, the liner 426 may be formed continuously around each lateral recess 424 and adjacent vertical cavity 406, and may be formed using an atomic layer deposition (ALD) process. In some instances, the liner 426 may be or may include carbon (C). During a same or subsequent manufacturing step, the fourth material 422 may be deposited inside the liner 426. For example, the fourth material 422 may be deposited in each lateral recess 424 and each vertical cavity 406 such that it is in contact with the liner 426 and is continuous around each lateral recess 424 and adjacent vertical cavity 406. In some examples, during a later manufacturing step, the fourth material 422 inside the lateral recesses 424 may support the formation of one or more pillars (e.g., digit lines). The fourth material 422 may include a conductive material, such as a metal material. In some instances, the fourth material 422 may be tungsten.

FIG. 4H shows an example of a top-down view of a memory architecture 400-h that supports memory cell formation in pier and pillar architecture in accordance with examples as disclosed herein. FIG. 4H may illustrate an oxide material 427 being formed (e.g., deposited) in each lateral recess 424 and vertical cavity 406, which may support forming multiple pillars per pillar opening using a reduced or otherwise streamlined quantity of manufacturing steps as described herein. In some instances, the oxide material 427 may be a same material as the second material 404.

In some instances, the second material 404 may be deposited in each lateral recess 424 and each vertical cavity 406 such that it is in contact with the fourth material 422 and is continuous around each lateral recess 424 and adjacent vertical cavity 406. In some instances, a gap may be left in each vertical cavity 406 to support the removal of one or more materials during a later manufacturing step. In some examples, the combination of the second material 404 and the fourth material 422 may collectively be referred to as a fifth material.

FIG. 4I shows an example of a top-down view of a memory architecture 400-i that supports memory cell formation in pier and pillar architecture in accordance with examples as disclosed herein. FIG. 4I may illustrate the second material 404 and the fourth material 422 being removed from at least a portion of each vertical cavity 406, which may support forming multiple pillars per pillar opening using a reduced or otherwise streamlined quantity of manufacturing steps as described herein.

In some instances, the second material 404 and the fourth material 422 may be removed from at least a portion of each vertical cavity 406. For example, the second material 404 and the fourth material 422 may be removed to expose a portion of the liner 426 in each vertical cavity 406. The second material 404 and the fourth material 422 may be removed by a selective etching process that utilizes a wet etching process or a dry etching process. In some instances, the second material 404 and the fourth material 422 may be removed during a same etching process (e.g., a single etching process) or during different etching processes (e.g., multiple etching processes), and may utilize a same or a different etchant or etching process. In some instances, the liner 426 may prevent the first material 402 and the liner 412, included in the first region 414 and the second region 416, from being etched. The liner 426 may also protect the fourth material 422 at the first layer 401 of the stack of materials.

Portions of the second material 404 and the fourth material 422 included in the lateral recesses 424 may not be removed (e.g., etched, exhumed) when removing the second material 404 and the fourth material 422 from each vertical cavity 406. Additionally, or alternatively, a portion of the second material 404, the fourth material 422, or both included in the lateral recesses 424 may extend into at least a portion of each vertical cavity 406. In other examples, the second material 404 may extend past the fourth material 422 (e.g., into a respective vertical cavity 406). Accordingly, conductive pillars 436 may be formed, where each conductive pillar 436 extends vertically through the first layers 401 and the second layers 403. As illustrated in FIG. 4I, two pillars (e.g., pillars 436-a and 436-b) may be formed within each pillar opening (each of the cavities 410 shown in FIG. 4B).

FIG. 4J shows an example of a top-down view of a memory architecture 400-j that supports memory cell formation in pier and pillar architecture in accordance with examples as disclosed herein. FIG. 4J may illustrate the liner 426 being removed from each vertical cavity 406, which may support forming multiple pillars per pillar opening using a reduced or otherwise streamlined quantity of manufacturing steps as described herein.

In some instances, the liner 426 may be removed from at least a portion of each vertical cavity 406. For example, the liner 426 may be removed to expose a portion of the fourth material 422 adjacent to each vertical cavity 406. The liner 426 may be removed by a selective etching process that utilizes a wet etching process or a dry etching process. After removing the liner 426, portions of the first material 402 included in the first region 414 and the second region 416 may be exposed and may be etched (e.g., removed) during a later manufacturing step. Portions the liner 426 included in the lateral recesses 424 may not be removed (e.g., etched, exhumed) when removing the liner 426 from each vertical cavity 406.

FIG. 4K shows an example of a top-down view of a memory architecture 400-k that supports memory cell formation in pier and pillar architecture in accordance with examples as disclosed herein. FIG. 4K may illustrate a liner 428 (e.g., an electrode liner, a first electrode liner) being formed (e.g., deposited, selectively formed) in each vertical cavity 406, which may support forming multiple pillars per pillar opening using a reduced or otherwise streamlined quantity of manufacturing steps as described herein.

In some instances, the liner 428 may be selectively formed (e.g., deposited) in one or more portions of each vertical cavity 406. The liner 428 may also be formed such that it is in contact with a portion of the fourth material 422 located in the lateral recesses 424, and may be formed using an ALD process. The liner 428 may be selectively formed at the first layers 401 of the stack of materials that include the fourth material 422. In some instances, the liner 428 may be or may include carbon (C), and may be a same or different material as the liner 426. For example, the liner 428 may be formed at an upper portion and a lower portion of each vertical cavity 406, such that a portion of the first material 402 included in the first region 414 and the second region 416 may be exposed (e.g., not in contact with the liner 428). The liner may be selectively formed on exposed metal (e.g., fourth material 422) surfaces. In some instances, a portion of the liner 412 may also be exposed. The liner 428 may protect the fourth material 422 from being etched during a later manufacturing step.

FIG. 4L shows an example of a top-down view of a memory architecture 400-1 that supports memory cell formation in pier and pillar architecture in accordance with examples as disclosed herein. FIG. 4L may illustrate a portion of the first material 402 and the liner 412 of the first region 414 and the second region 416 being removed (e.g., etched), which may support forming multiple pillars per pillar opening using a reduced or otherwise streamlined quantity of manufacturing steps as described herein.

In some instances, a portion of the first material 402 and the liner 412 of the first region 414 and the second region 416 may be removed to form cavities 430 (e.g., second cavities) in the first region 414 and the second region 416. For example, a selective etching process may be performed at the layers of the first material 402. In some instances, the liner 412 and the first material 402 may be removed during a same etching process (e.g., a single etching process) or during different etching processes (e.g., multiple etching processes), and may utilize a same or a different etchant or etching process. Additionally, or alternatively, the liner 412 and the first material 402 may be removed via the respective exposed portions that are adjacent to the vertical cavities 406.

The selective etching process may be performed using a wet etching process or a dry etching process and may form a first cavity 430-a, a second cavity 430-b, a third cavity 430-c, and a fourth cavity 430-d. The cavities 430 may be formed between conductive pillars 436 and word lines at respective layers of the stack of materials. Each of the cavities 430 may be adjacent to a portion of the fourth material 422 and may support the formation of one or more memory cells during a later manufacturing step. In some instances, each cavity 430 may be adjacent to a respective portion of the liner 428 that is present on conductive pillars 436.

FIG. 4M shows an example of a top-down view of a memory architecture 400-m that supports memory cell formation in pier and pillar architecture in accordance with examples as disclosed herein. FIG. 4M may illustrate a liner 432 (e.g., an electrode liner, a second electrode liner) being formed (e.g., deposited, selectively formed) in each cavity 430, which may support forming multiple pillars per pillar opening using a reduced or otherwise streamlined quantity of manufacturing steps as described herein.

In some instances, the liner 432 may be selectively formed (e.g., deposited) in one or more portions of cavity 430. The liner 432 may also be formed such that it is in contact with a portion of the fourth material 422, and may be formed using an ALD process. The liner 432 may be formed at the first layers 401 of the stack of materials. In some instances, the liner 432 may be or may include carbon (C), and may be a same or different material as the liner 426 and the liner 428. For example, the liner 432 may be formed at an upper portion of each cavity 430, such that the fourth material 422 is protected during a later manufacturing step. As described herein, the liner 432 may also be used as an electrode for cell (e.g., memory cell) formation.

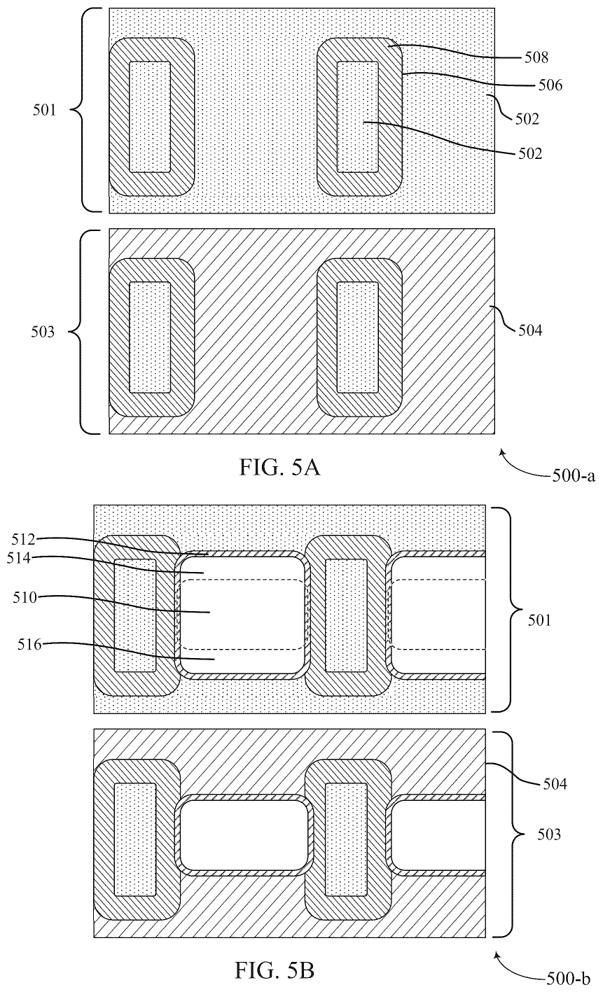

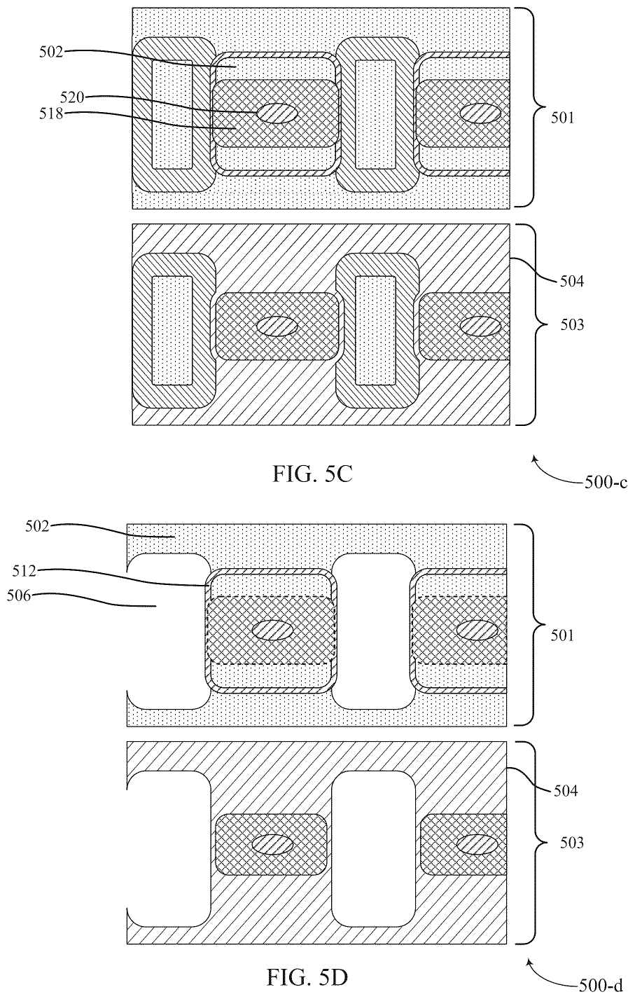

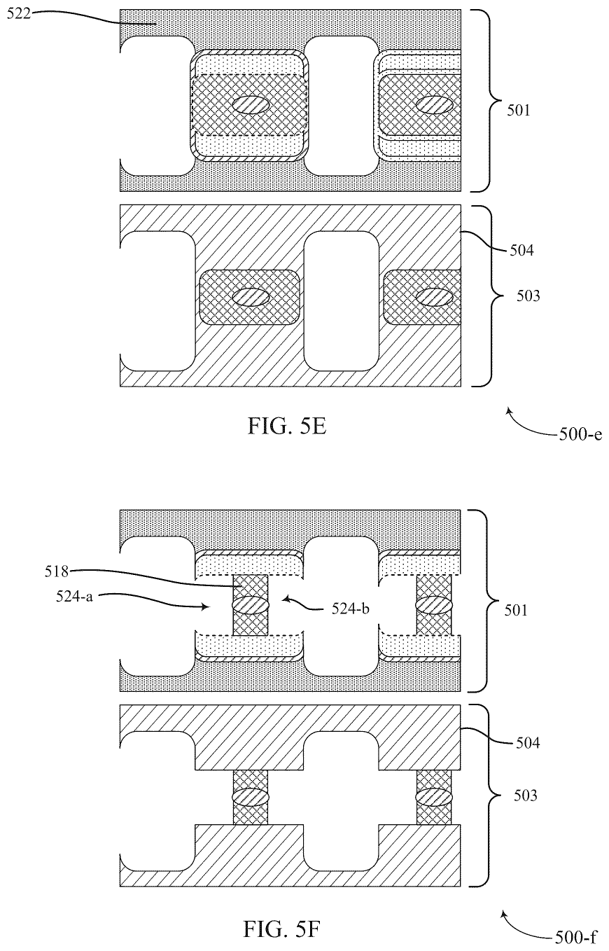

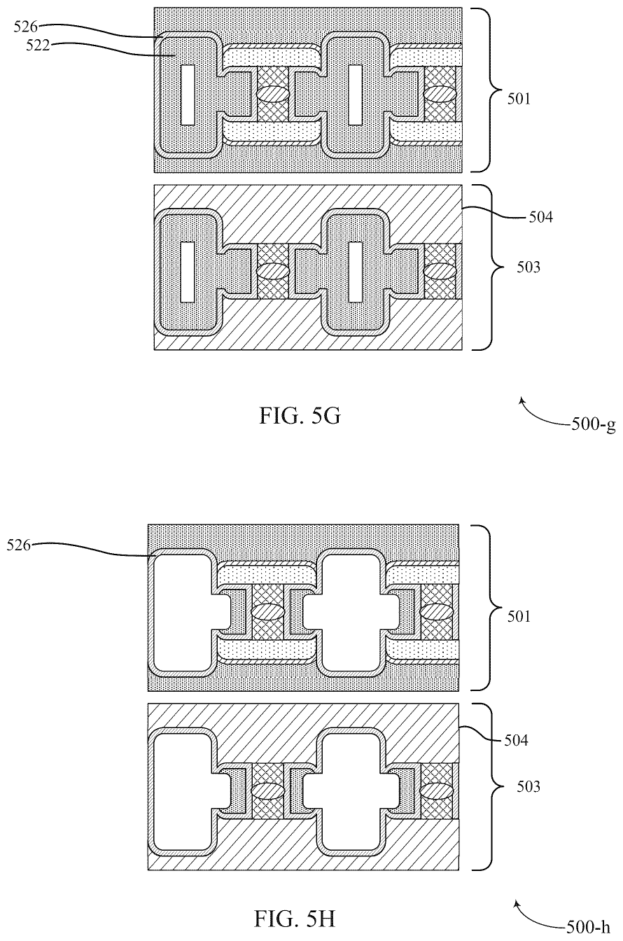

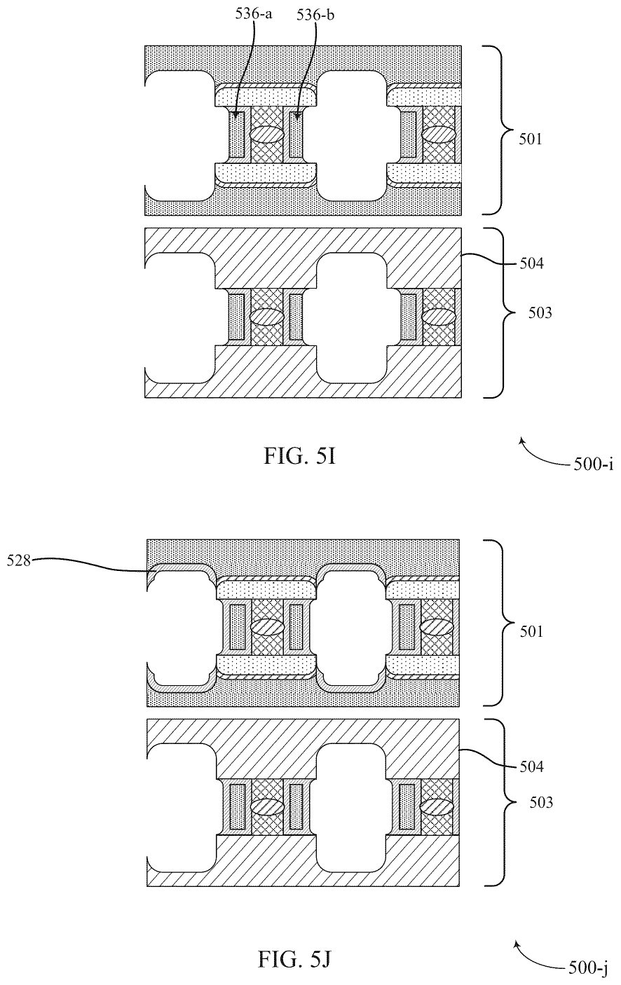

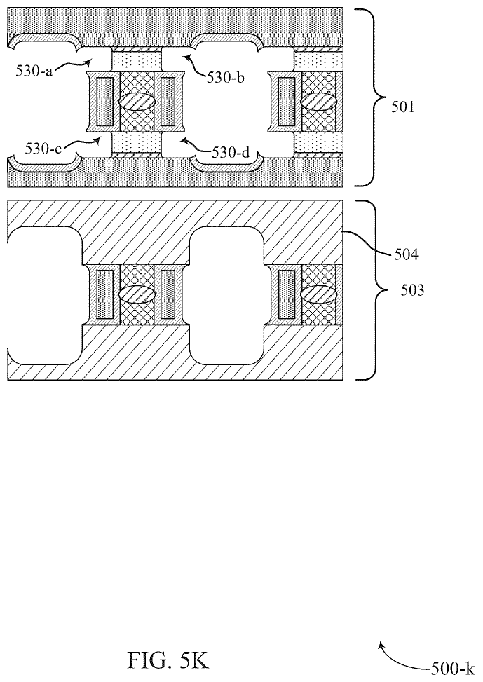

In some examples, the manufacturing steps described with reference to FIG. 4M may be performed on the structure illustrated in FIG. 5K. That is, the manufacturing steps may be performed on the structure illustrated in FIG. 5K to form a liner (e.g., an electrode liner, a first electrode liner) in each cavity, which may support forming multiple pillars per pillar opening using a reduced or otherwise streamlined quantity of manufacturing steps as described herein

FIG. 4N shows an example of a top-down view of a memory architecture 400-n that supports memory cell formation in pier and pillar architecture in accordance with examples as disclosed herein. FIG. 4N may illustrate one or more memory cells 434 being formed in each cavity 430, which may support forming multiple pillars per pillar opening using a reduced or otherwise streamlined quantity of manufacturing steps as described herein.

The memory cells 434 may be formed such that each memory cell 434 is in contact with a pillar 436. For example, a first memory cell 434-a, a second memory cell 434-b, a third memory cell 434-c, and a fourth memory cell 434-d may be formed in the respective cavities 430. The first memory cell 434-a and the third memory cell 434-c may be in contact with a pillar 436-a (e.g., a bit line) and the second memory cell 434-b and the fourth memory cell 434-d may be in contact with a pillar 436-b (e.g., a bit line), where pillars 436-a and 436-b are formed within one pillar opening (e.g., cavity 410 as illustrated in FIG. 4B).

In some examples, each vertical cavity 406 may be filled with the third material 418 to form a plurality of piers. Each pier may separate (e.g., be located between) pillars 436 that are coupled with respective memory cells 434. Accordingly, the manufacturing steps described herein with reference to FIGS. 4A-4N may support forming multiple pillars per pillar opening in a pier and pillar architecture using a reduced or otherwise streamlined quantity of manufacturing steps relative to conventional manufacturing operations.

In some examples, the manufacturing steps described with reference to FIG. 4N may be performed on the structure illustrated in FIG. 5K. That is, the manufacturing steps may be performed on the structure illustrated in FIG. 5K, after performing the manufacturing steps described in FIG. 4M, to form one or more memory cells in each cavity, which may support forming multiple pillars per pillar opening using a reduced or otherwise streamlined quantity of manufacturing steps as described herein.

FIG. 5A shows an example of a top-down view of a memory architecture 500-a that supports memory cell formation in pier and pillar architecture in accordance with examples as disclosed herein. FIG. 5A may illustrate one or more vertical cavities 506 being formed in a stack of materials, which may support forming multiple pillars per pillar opening using a reduced or otherwise streamlined quantity of manufacturing steps as described herein.

In some instances, the memory architecture 500-a may illustrate a first layer 501 of a stack of materials and a second layer 503 of a stack of materials. For example, the first layer 501 may include a first material 502 and the second layer 503 may include a second material 504. In some instances, the first material 502 may be a nitride material and the second material 504 may be an oxide material. The stack of materials may include alternating layers of the first material 502 and the second material 504, which may have been deposited in a prior manufacturing step. The stack of materials may include any quantity of layers.

In some instances, one or more vertical cavities 506 may have been formed through the stack of materials in a prior manufacturing step. The vertical cavities 506 may be formed to support pier formation during a later manufacturing step, and may be formed through the layers including the first material 502 (e.g., the first layers 501) and the layers including the second material 504 (e.g., the second layers 503). For example, each vertical cavity 506 may represent a location in the stack of materials in which a pier is formed. In some examples, each vertical cavity 506 may include the first material 502 (e.g., a nitride material) that is surrounded by a liner 508. In some instances, the liner 508 may include a silicon carbonitride, a carbon-doped material, or a boron-doped material. The first material 502 and the liner 508 of the vertical cavities 506 may be sacrificial materials, meaning that they may be removed partially or entirely during one or more subsequent manufacturing steps.

FIG. 5B shows an example of a top-down view of a memory architecture 500-b that supports memory cell formation in pier and pillar architecture in accordance with examples as disclosed herein. FIG. 5B may illustrate one or more cavities 510 being formed between each vertical cavity 506, which may support forming multiple pillars per pillar opening using a reduced or otherwise streamlined quantity of manufacturing steps as described herein.

In some instances, the memory architecture 500-b may illustrate one or more cavities 510 formed between each vertical cavity 506. In some instances, each cavity 510 may be referred to as a third cavity or as a pillar opening. The cavities 510 may be formed in the stack of materials using an etching process, such as wet etching process or a dry etching process. The cavities 510 may be formed to support pillar formation during a later manufacturing step, and may be formed through the layers including the first material 502 and the layers including the second material 504. In some instances, a liner 512 may be formed in each cavity 510. The liner 512 may be a dielectric material (e.g., an oxide material) and may be deposited to protect materials deposited within each cavity 510 during later manufacturing steps. The liner 512 may be formed at the layers including the first material 502 and the layers including the second material 504.

In some instances, the cavities 510 may be adjacent to one or more regions to be filled with a material during a later manufacturing step. For example, each cavity 510 may be adjacent to a first region 514 and a second region 516. In some instances, the first layer 501 may be recessed by etching through the cavities 510 (e.g., using a different etch than used to form the cavities 510). The first region 514 and the second region 516 may eventually be filled with the first material 502 (e.g., a portion of the liner 512 of the first region 514 may partially surround the first material 502 deposited in the cavity 510, a portion of the liner 512 of the second region 516 may partially surround the first material 502 deposited in the cavity 510). The first region 514 and the second region 516 may surround the cavities 510 in which a polysilicon material, hafnium oxide, silicon oxide, or a combination thereof may be deposited in during a later manufacturing step.

In some instances, the first region 514 and the second region 516 may exist in the stack of materials at the first layers 501 (e.g., layers of the first material 502). For example, the plurality of cavities 510 may extend through layers of the first material 502 and layers of the second material 504, and recesses may be formed (e.g., at the first layer 501) into the first region 514 and the second region 516. The recesses may be formed into the first region 514 and the second region 516 using a selective etching process, which may utilize a wet etching process or a dry etching process.

FIG. 5C shows an example of a top-down view of a memory architecture 500-c that supports memory cell formation in pier and pillar architecture in accordance with examples as disclosed herein. FIG. 5C may illustrate one or more cavities 510 being filled with a third material 518 (e.g., to form a column of third material 518), which may support forming multiple pillars per pillar opening using a reduced or otherwise streamlined quantity of manufacturing steps as described herein.

In some instances, third material 518 may be deposited in each cavity 510. The third material 518 may be a dielectric or seal material (e.g., polysilicon material, hafnium oxide, silicon oxide, or a combination thereof). Additionally, or alternatively, the third material 518 may be deposited such that an opening 520 exists in the third material 518. The opening may be filled by a second material 504. In some examples, the opening 520 may be formed by selectively etching the third material 518. The opening 520 may be used, during a later manufacturing step, to remove portions of the third material 518 for pillar formation. Filing the opening 520 with the second material 504 may prevent the opening 520 from undesirable results (e.g., blowing up) during a later manufacturing step (e.g., when recessing the third material 518 through the vertical cavity 506). Further, the first material 502 may be deposited in each of the first region 514 and the second region 516 such that a portion of the first material 502 is adjacent to the third material 518 and the liner 512.

FIG. 5D shows an example of a top-down view of a memory architecture 500-d that supports memory cell formation in pier and pillar architecture in accordance with examples as disclosed herein. FIG. 5D may illustrate the materials from each vertical cavity 506 being exhumed (e.g., etched, removed), which may support forming multiple pillars per pillar opening using a reduced or otherwise streamlined quantity of manufacturing steps as described herein.

In some instances, the first material 502 and the liner 508 may be removed from each vertical cavity 506 (e.g., at layers of the first material 502 and layers of the second material 504). In some examples, the first material 502 and the liner 508 may be removed using a wet etching process or a dry etching process. The first material 502 and the liner 508 may be removed such that each vertical cavity 506 does not include any materials, and such that a portion of the liner 512 is exposed.

FIG. 5E shows an example of a top-down view of a memory architecture 500-e that supports memory cell formation in pier and pillar architecture in accordance with examples as disclosed herein. FIG. 5E may illustrate a metallization process performed at the first layer 501 of the stack of materials, which may support forming multiple pillars per pillar opening using a reduced or otherwise streamlined quantity of manufacturing steps as described herein.

In some instances, FIG. 5E may illustrate a replacement gate (RG) process where layers of the first material 502 of the stack of materials are replaced with a fourth material 522. For example, the RG process may be performed via the vertical cavities 506. In some instances the fourth material 522 may be a metal material, such as tungsten (W), and the RG process may support the formation of word lines in the stack of materials. As shown in FIG. 5E, the RG process may not occur at layers of the second material 504.

FIG. 5F shows an example of a top-down view of a memory architecture 500-f that supports memory cell formation in pier and pillar architecture in accordance with examples as disclosed herein. FIG. 5F may illustrate portions of the third material 518 (e.g., a portion of the columns of the third material 518) being removed, which may support forming multiple pillars per pillar opening using a reduced or otherwise streamlined quantity of manufacturing steps as described herein.

In some instances, a portion of the columns of the third material 518 may be removed to form lateral recesses 524 in the columns of the third material 518. A portion of the liner 512 may also be removed. For example, a selective etching process may be performed at the layers of the first material 502 and the layers of the second material 504. In some instances, the liner 512 and the third material 518 may be removed during a same etching process (e.g., a single etching process) or during different etching processes (e.g., multiple etching processes), and may utilize a same or a different etchant or etching process.

The selective etching process may be performed using a wet etching process or a dry etching process and may form a respective first lateral recess 524-a and a second lateral recess 524-b in each column of the third material 518 (e.g., in each pillar opening). The etching process may remove a portion of the liner 512 and a portion of the third material 518 such that the first material 502 of the first region 514 and the first material 502 of the second region 516 is adjacent to the respective lateral recesses 524.

FIG. 5G shows an example of a top-down view of a memory architecture 500-g that supports memory cell formation in pier and pillar architecture in accordance with examples as disclosed herein. FIG. 5G may illustrate a liner 526 (e.g., an electrode liner, a first electrode liner) and the fourth material 522 being formed (e.g., deposited) in each lateral recess 524 and vertical cavity 506, which may support forming multiple pillars per pillar opening using a reduced or otherwise streamlined quantity of manufacturing steps as described herein.

In some instances, the liner 526 may extend around a perimeter of each lateral recess 524 and around the perimeter of each vertical cavity 506. For example, the liner 526 may be formed continuously around each lateral recess 524 and adjacent vertical cavity 506, and may be formed using an atomic layer deposition (ALD) process. In some instances, the liner 526 may be or may include carbon (C). During a same or subsequent manufacturing step, the fourth material 522 may be deposited inside the liner 526. For example, the fourth material 522 may be deposited in each lateral recess 524 and each vertical cavity 506 such that it is in contact with the liner 526 and is continuous around each lateral recess 524 and adjacent vertical cavity 506. In some examples, during a later manufacturing step, the fourth material 522 inside the lateral recesses 524 may support the formation of one or more pillars (e.g., digit lines).

In some instances, a relatively greater quantity of the fourth material 522 may be deposited in each vertical cavity 506 relative to the manufacturing process described with reference to FIG. 4G. That is, the architecture 500 may support only the fourth material 522 being deposited in each vertical cavity (e.g., not the second material 404 as described with reference to FIG. 4H). Accordingly, a thickness of the fourth material 522 included each vertical cavity 506 and in each lateral recess 524 may be greater than described with reference to the memory architecture 400. The increased thickness may reduce the resistance of the resulting digit line, and the increased length of the lateral recesses 524 may cause more spread on the thickness of the residual fourth material 522, which may be beneficial.

FIG. 5H shows an example of a top-down view of a memory architecture 500-h that supports memory cell formation in pier and pillar architecture in accordance with examples as disclosed herein. FIG. 5H may illustrate the fourth material 522 being removed from at least a portion of each vertical cavity 506, which may support forming multiple pillars per pillar opening using a reduced or otherwise streamlined quantity of manufacturing steps as described herein.

In some instances, the fourth material 522 may be removed from at least a portion of each vertical cavity 506. For example, the fourth material 522 may be removed to expose a portion of the liner 526 in each vertical cavity 506. The fourth material 522 may be removed by a selective etching process that utilizes a wet etching process or a dry etching process. In some instances, the liner 526 may prevent the liner 512 and the first material 502 included in the first region 514 and the second region 516 from being etched. The liner 526 may also protect the fourth material 522 at the first layer 501 of the stack of materials.

Portions the fourth material 522 included in the lateral recesses 524 may not be removed (e.g., etched, exhumed) when removing the fourth material 522 from each vertical cavity 506. Additionally, or alternatively, a portion of the fourth material 522 included in the lateral recesses 524 may extend into at least a portion of each vertical cavity 506. In other examples, the fourth material 522 may be generally aligned (e.g., coplanar) with a portion of the liner 526.

FIG. 5I shows an example of a top-down view of a memory architecture 500-i that supports memory cell formation in pier and pillar architecture in accordance with examples as disclosed herein. FIG. 5I may illustrate the liner 526 being removed from each vertical cavity 506, which may support forming multiple pillars per pillar opening using a reduced or otherwise streamlined quantity of manufacturing steps as described herein.

In some instances, the liner 526 may be removed from at least a portion of each vertical cavity 506. For example, the liner 526 may be removed to expose a portion of the fourth material 522 adjacent to each vertical cavity 506. The liner 526 may be removed by a selective etching process that utilizes a wet etching process or a dry etching process. After removing the liner 526, portions of the first material 502 included in the first region 514 and the second region 516 may be exposed and may be etched (e.g., removed) during a later manufacturing step. Portions the liner 526 included in the lateral recesses 524 may not be removed (e.g., etched, exhumed) when removing the liner 526 from each vertical cavity 506. Accordingly, conductive pillars 536 may be formed, where each conductive pillar 536 extends vertically through the first layers 501 and the second layers 503. In addition, FIG. 5I illustrates that multiple conductive pillars 536 (e.g., pillar 536-a and pillar 536-b) may be formed within each pillar opening (e.g., corresponding to each cavity 510 of FIG. 5B).

FIG. 5J shows an example of a top-down view of a memory architecture 500-j that supports memory cell formation in pier and pillar architecture in accordance with examples as disclosed herein. FIG. 5J may illustrate a liner 528 (e.g., an electrode liner, a first electrode liner) being formed (e.g., deposited, selectively formed) in each vertical cavity 506, which may support forming multiple pillars per pillar opening using a reduced or otherwise streamlined quantity of manufacturing steps as described herein.

In some instances, the liner 528 may be selectively formed (e.g., deposited) in one or more portions of each vertical cavity 506. The liner 528 may also be formed such that it is in contact with a portion of the fourth material 522 located in the lateral recesses 524, and may be formed using an ALD process. The liner 528 may be selectively formed at the first layer 501 of the tack of materials that include the fourth material 522. In some instances, the liner 528 may be or may include carbon (C), and may be a same or different material as the liner 526. For example, the liner 528 may be formed at an upper portion and a lower portion of each vertical cavity 506, such that a portion of the first material 502 included in the first region 514 and the second region 516 may be exposed (e.g., not in contact with the liner 528). In some instances, a portion of the liner 512 may also be exposed. The liner 528 may protect the fourth material 522 from being etched during a later manufacturing step.

FIG. 5K shows an example of a top-down view of a memory architecture 500-k that supports memory cell formation in pier and pillar architecture in accordance with examples as disclosed herein. FIG. 5K may illustrate a portion of the first material 502 and the liner 512 of the first region 514 and the second region 516 being removed (e.g., etched), which may support forming multiple pillars per pillar opening using a reduced or otherwise streamlined quantity of manufacturing steps as described herein.

In some instances, a portion of the first material 502 and the liner 512 of the first region 514 and the second region 516 may be removed to form cavities 530 (e.g., second cavities) in the first region 514 and the second region 516. For example, a selective etching process may be performed at the first layer 501 of the stack of materials. In some instances, the liner 512 and the first material 502 may be removed during a same etching process (e.g., a single etching process) or during different etching processes (e.g., multiple etching processes), and may utilize a same or a different etchant or etching process. Additionally, or alternatively, the liner 512 and the first material 502 may be removed via the respective exposed portions that are adjacent to the vertical cavities 506.

The selective etching process may be performed using a wet etching process or a dry etching process and may form a first cavity 530-a, a second cavity 530-b, a third cavity 530-c, and a fourth cavity 530-d (e.g., within each of the pillar openings). Each of the cavities 530 may be adjacent to a portion of the fourth material 522 and may support the formation of one or more memory cells during a later manufacturing step. In some instances, each cavity 530 may be adjacent to a respective portion of the liner 526.

As described herein, the manufacturing steps described with reference to FIG. 4M may be performed on the structure illustrated in FIG. 5K. That is, the manufacturing steps may be performed on the structure illustrated in FIG. 5K to form a liner (e.g., an electrode liner, a second electrode liner) in each cavity. After performing the manufacturing steps described with reference to FIG. 4M, the manufacturing steps described with reference to FIG. 4N may be performed. Such manufacturing steps may form one or more memory cells in each cavity, which may support forming multiple pillars per pillar opening using a reduced or otherwise streamlined quantity of manufacturing steps as described herein.

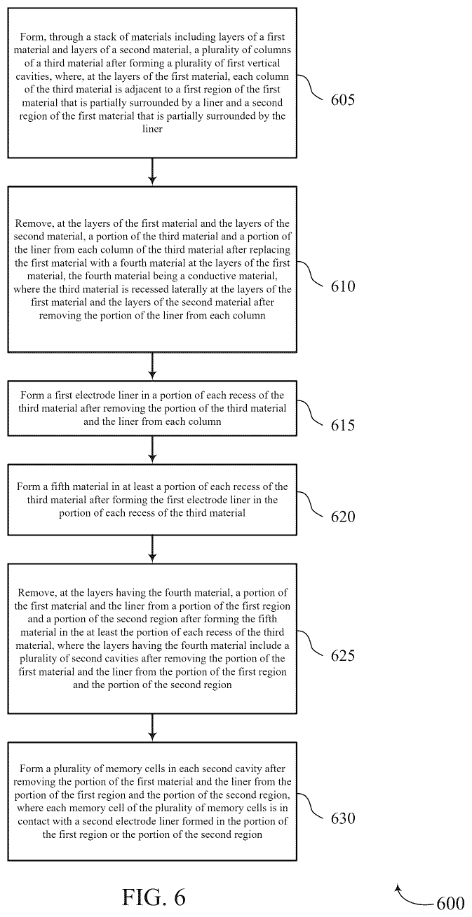

FIG. 6 shows a flowchart illustrating a method 600 that supports memory cell formation in pier and pillar architecture in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming, through a stack of materials including layers of a first material and layers of a second material, a plurality of columns of a third material after forming a plurality of first vertical cavities, where, at the layers of the first material, each column of the third material is adjacent to a first region of the first material that is partially surrounded by a liner and a second region of the first material that is partially surrounded by the liner.

At 610, the method may include removing, at the layers of the first material and the layers of the second material, a portion of the third material and a portion of the liner from each column of the third material after replacing the first material with a fourth material at the layers of the first material, the fourth material being a conductive material, where the third material is recessed laterally at the layers of the first material and the layers of the second material after removing the portion of the liner from each column.

At 615, the method may include forming a first electrode liner in a portion of each recess of the third material after removing the portion of the third material and the liner from each column.

At 620, the method may include forming a fifth material in at least a portion of each recess of the third material after forming the first electrode liner in the portion of each recess of the third material.

At 625, the method may include removing, at the layers having the fourth material, a portion of the first material and the liner from a portion of the first region and a portion of the second region after forming the fifth material in the at least the portion of each recess of the third material, where the layers having the fourth material include a plurality of second cavities after removing the portion of the first material and the liner from the portion of the first region and the portion of the second region.

At 630, the method may include forming a plurality of memory cells in each second cavity after removing the portion of the first material and the liner from the portion of the first region and the portion of the second region, where each memory cell of the plurality of memory cells is in contact with a second electrode liner formed in the portion of the first region or the portion of the second region.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for forming, through a stack of materials including layers of a first material and layers of a second material, a plurality of columns of a third material after forming a plurality of first vertical cavities, where, at the layers of the first material, each column of the third material is adjacent to a first region of the first material that is partially surrounded by a liner and a second region of the first material that is partially surrounded by the liner; removing, at the layers of the first material and the layers of the second material, a portion of the third material and a portion of the liner from each column of the third material after replacing the first material with a fourth material at the layers of the first material, the fourth material being a conductive material, where the third material is recessed laterally at the layers of the first material and the layers of the second material after removing the portion of the liner from each column; forming a first electrode liner in a portion of each recess of the third material after removing the portion of the third material and the liner from each column; forming a fifth material in at least a portion of each recess of the third material after forming the first electrode liner in the portion of each recess of the third material; removing, at the layers having the fourth material, a portion of the first material and the liner from a portion of the first region and a portion of the second region after forming the fifth material in the at least the portion of each recess of the third material, where the layers having the fourth material include a plurality of second cavities after removing the portion of the first material and the liner from the portion of the first region and the portion of the second region; and forming a plurality of memory cells in each second cavity after removing the portion of the first material and the liner from the portion of the first region and the portion of the second region, where each memory cell of the plurality of memory cells is in contact with a second electrode liner formed in the portion of the first region or the portion of the second region.

Aspect 2: The method, apparatus, or non-transitory computer-readable medium of aspect 1, further including operations, features, circuitry, logic, means, or instructions, or any combination thereof for forming, at the layers of the first material, the second electrode liner in the portion of the first region and the portion of the second region after removing the portion of the first material and the liner from the portion of the first region and the portion of the second region.

Aspect 3: The method, apparatus, or non-transitory computer-readable medium of any of aspects 1 through 2, where forming the fifth material in the portion each recess of the third material includes operations, features, circuitry, logic, means, or instructions, or any combination thereof for depositing, at the layers of the first material and the layers of the second material, the second material and the fourth material in each first vertical cavity and each recess of the third material and removing, from the layers of the first material and the layers of the second material, a portion of the second material and the fourth material from each first vertical cavity.

Aspect 4: The method, apparatus, or non-transitory computer-readable medium of aspect 3, further including operations, features, circuitry, logic, means, or instructions, or any combination thereof for removing the first electrode liner from each first vertical cavity after removing the portion of the second material and the fourth material from each first vertical cavity.

Aspect 5: The method, apparatus, or non-transitory computer-readable medium of aspect 4, further including operations, features, circuitry, logic, means, or instructions, or any combination thereof for forming, at the layers of the first material, a protective liner in a portion of each first vertical cavity after removing the first electrode liner from each first vertical cavity.

Aspect 6: The method, apparatus, or non-transitory computer-readable medium of any of aspects 3 through 5, further including operations, features, circuitry, logic, means, or instructions, or any combination thereof for removing the first electrode liner from each first vertical cavity after removing the portion of the fourth material from each first vertical cavity.

Aspect 7: The method, apparatus, or non-transitory computer-readable medium of any of aspects 1 through 6, where forming the fifth material in the portion each recess of the third material includes operations, features, circuitry, logic, means, or instructions, or any combination thereof for depositing, at the layers of the first material and the layers of the second material, the fourth material in each first vertical cavity and each recess of the third material and removing, from the layers of the first material and the layers of the second material, a portion of the fourth material from each first vertical cavity.

Aspect 8: The method, apparatus, or non-transitory computer-readable medium of any of aspects 1 through 7, where forming the plurality of columns through the layers of the first material and the layers of the second material includes operations, features, circuitry, logic, means, or instructions, or any combination thereof for etching a portion of the first material at the layers of the first material to form a plurality of third cavities; depositing, around the plurality of third cavities, the liner at the layers of the first material and the layers of the second material; depositing the first material into the plurality of third cavities; removing at least a portion of the first material deposited into the plurality of third cavities; and depositing the third material in the plurality of columns, where the third material is in contact with a portion of the liner and a portion of the first material in the third cavities.

Aspect 9: The method, apparatus, or non-transitory computer-readable medium of aspect 8, where the third material of each column includes an opening that is filled with the second material.

Aspect 10: The method, apparatus, or non-transitory computer-readable medium of any of aspects 1 through 9, further including operations, features, circuitry, logic, means, or instructions, or any combination thereof for depositing the third material in the plurality of first vertical cavities after removing the portion of the first material and the liner from the portion of the first region and the portion of the second region.

Aspect 11: The method, apparatus, or non-transitory computer-readable medium of any of aspects 1 through 10, where forming the plurality of first vertical cavities includes operations, features, circuitry, logic, means, or instructions, or any combination thereof for removing, at the layers of the first material and the layers of the second material, the first material and the liner from each first vertical cavity.

Aspect 12: The method, apparatus, or non-transitory computer-readable medium of aspect 11, further including operations, features, circuitry, logic, means, or instructions, or any combination thereof for removing the first material from each first vertical cavity and depositing the fourth material at the layers of the first material after removing the first material and the dielectric liner from each first vertical cavity.

Aspect 13: The method, apparatus, or non-transitory computer-readable medium of any of aspects 1 through 12, where the fourth material is deposited around each recess of the third material.

Aspect 14: The method, apparatus, or non-transitory computer-readable medium of any of aspects 1 through 13, further including operations, features, circuitry, logic, means, or instructions, or any combination thereof for forming the stack of materials including the layers of the first material and the second material over a substrate before forming the plurality of columns.

Aspect 15: The method, apparatus, or non-transitory computer-readable medium of any of aspects 1 through 14, where the first material includes a nitride material and the second material includes an oxide material.

Aspect 16: The method, apparatus, or non-transitory computer-readable medium of any of aspects 1 through 15, where the third material includes a polysilicon material, hafnium oxide, silicon oxide, or a combination thereof.

Aspect 17: The method, apparatus, or non-transitory computer-readable medium of any of aspects 1 through 16, where the fourth material includes a metal material.

Aspect 18: The method, apparatus, or non-transitory computer-readable medium of any of aspects 1 through 17, where the liner includes silicon carbonitride, a carbon-doped material, or a boron-doped material.

Aspect 19: The method, apparatus, or non-transitory computer-readable medium of any of aspects 1 through 18, where the first electrode liner includes carbon.

Aspect 20: The method, apparatus, or non-transitory computer-readable medium of any of aspects 1 through 19, where the liner is formed using an atomic layer deposition (ALD) process.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 21: An apparatus, including: a substrate; a stack of layers including a first material and a second material; a plurality of piers extending through the stack of layers, where a portion of each pier includes a third material; a plurality of pillars extending through the stack of layers, where a set of pillars is positioned between respective piers of the plurality of piers, where the set of pillars between respective piers are separated from each other by a third material, and the third material is separated from the first material at each of the layers of the first material in the stack of layers by a fourth material, and where each set of pillars includes a first bit line and a second bit line; a first plurality of memory cells in contact with the first bit line, where respective memory cells of the first plurality of memory cells are in contact with the first material at each of the layers of the first material in the stack of layers via respective electrode materials that extend, at each of the layers of the first material in the stack of layers, at least partially around a respective pier; and a second plurality of memory cells in contact with the second bit line, where respective memory cells of the second plurality of memory cells are in contact with the first material at each of the layers of the first material in the stack of layers via respective electrode materials that extend, at each of the layers of the first material in the stack of layers, at least partially around a respective pier.

Aspect 22: The apparatus of aspect 21, where each of the plurality of pillars includes a conductive material and an electrode material, the electrode material of the plurality of pillars extends partially around the conductive material.

Aspect 23: The apparatus of any of aspects 21 through 22, where the respective electrode materials extend, at each of the layers of the first material in the stack of layers, between a first memory cell associated with a first pillar and a second memory cell associated with a second pillar, the first pillar and the second pillar are separated by a pier.

Aspect 24: The apparatus of any of aspects 21 through 23, where the third material is separated from the first material at each of the layers of the first material in the stack of layers by the fourth material and a fifth material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming, through a stack of materials comprising layers of a first material and layers of a second material, a plurality of columns of a third material after forming a plurality of first vertical cavities, wherein, at the layers of the first material, each column of the third material is adjacent to a first region of the first material that is partially surrounded by a liner and a second region of the first material that is partially surrounded by the liner;
removing, at the layers of the first material and the layers of the second material, a portion of the third material and a portion of the liner from each column of the third material after replacing the first material with a fourth material at the layers of the first material, the fourth material being a conductive material, wherein the third material is recessed laterally at the layers of the first material and the layers of the second material after removing the portion of the liner from each column;
forming a first electrode liner in a portion of each recess of the third material after removing the portion of the third material and the liner from each column;
forming a fifth material in at least a portion of each recess of the third material after forming the first electrode liner in the portion of each recess of the third material;
removing, at the layers having the fourth material, a portion of the first material and the liner from a portion of the first region and a portion of the second region after forming the fifth material in the at least the portion of each recess of the third material, wherein the layers having the fourth material comprise a plurality of second cavities after removing the portion of the first material and the liner from the portion of the first region and the portion of the second region; and
forming a plurality of memory cells in each second cavity after removing the portion of the first material and the liner from the portion of the first region and the portion of the second region, wherein each memory cell of the plurality of memory cells is in contact with a second electrode liner formed in the portion of the first region or the portion of the second region.

2. The method of claim 1, further comprising:
forming, at the layers of the first material, the second electrode liner in the portion of the first region and the portion of the second region after removing the portion of the first material and the liner from the portion of the first region and the portion of the second region.

3. The method of claim 1, wherein forming the fifth material in the portion each recess of the third material comprises:
depositing, at the layers of the first material and the layers of the second material, the second material and the fourth material in each first vertical cavity and each recess of the third material; and
removing, from the layers of the first material and the layers of the second material, a portion of the second material and the fourth material from each first vertical cavity.

4. The method of claim 3, further comprising:
removing the first electrode liner from each first vertical cavity after removing the portion of the second material and the fourth material from each first vertical cavity.

5. The method of claim 4, further comprising:
forming, at the layers of the first material, a protective liner in a portion of each first vertical cavity after removing the first electrode liner from each first vertical cavity.

6. The method of claim 1, wherein forming the fifth material in the portion each recess of the third material comprises:
depositing, at the layers of the first material and the layers of the second material, the fourth material in each first vertical cavity and each recess of the third material; and
removing, from the layers of the first material and the layers of the second material, a portion of the fourth material from each first vertical cavity.

7. The method of claim 3, further comprising:
removing the first electrode liner from each first vertical cavity after removing the portion of the fourth material from each first vertical cavity.

8. The method of claim 1, wherein forming the plurality of columns through the layers of the first material and the layers of the second material comprises:
etching a portion of the first material at the layers of the first material to form a plurality of third cavities;
depositing, around the plurality of third cavities, the liner at the layers of the first material and the layers of the second material;
depositing the first material into the plurality of third cavities;
removing at least a portion of the first material deposited into the plurality of third cavities; and
depositing the third material in the plurality of columns, wherein the third material is in contact with a portion of the liner and a portion of first material in the third cavities.

9. The method of claim 8, wherein the third material of each column comprises an opening that is filled with the second material.

10. The method of claim 1, further comprising:
depositing the third material in the plurality of first vertical cavities after removing the portion of the first material and the liner from the portion of the first region and the portion of the second region.

11. The method of claim 1, wherein forming the plurality of first vertical cavities comprises:
removing, at the layers of the first material and the layers of the second material, the first material and the liner from each first vertical cavity.

12. The method of claim 1, wherein the fourth material is deposited around each recess of the third material.

13. The method of claim 1, further comprising:
forming the stack of materials comprising the layers of the first material and the second material over a substrate before forming the plurality of columns.

14. The method of claim 11, further comprising:
removing the first material from each first vertical cavity; and
depositing the fourth material at the layers of the first material after removing the first material and the dielectric liner from each first vertical cavity.

15. The method of claim 1, wherein the first material comprises a nitride material and the second material comprises an oxide material.

16. The method of claim 1, wherein the third material comprises a polysilicon material, hafnium oxide, silicon oxide, or a combination thereof.

17. The method of claim 1, wherein the fourth material comprises a metal material.

18. The method of claim 1, wherein the liner comprises silicon carbonitride, a carbon-doped material, or a boron-doped material.

19. The method of claim 1, wherein the first electrode liner comprises carbon.

20. The method of claim 1, wherein the liner is formed using an atomic layer deposition (ALD) process.

21. An apparatus, comprising:
a substrate;
a stack of layers comprising a first material and a second material;
a plurality of piers extending through the stack of layers, wherein a portion of each pier comprises a third material;
a plurality of pillars extending through the stack of layers, wherein a set of pillars is positioned between respective piers of the plurality of piers, wherein the set of pillars between respective piers are separated from each other by a third material, and the third material is separated from the first material at each of the layers of the first material in the stack of layers by a fourth material, and wherein each set of pillars comprises a first bit line and a second bit line;
a first plurality of memory cells in contact with the first bit line, wherein respective memory cells of the first plurality of memory cells are in contact with the first material at each of the layers of the first material in the stack of layers via respective electrode materials that extend, at each of the layers of the first material in the stack of layers, at least partially around a respective pier; and
a second plurality of memory cells in contact with the second bit line, wherein respective memory cells of the second plurality of memory cells are in contact with the first material at each of the layers of the first material in the stack of layers via respective electrode materials that extend, at each of the layers of the first material in the stack of layers, at least partially around a respective pier.

22. The apparatus of claim 21, wherein each of the plurality of pillars comprises a conductive material and an electrode material, wherein the electrode material of the plurality of pillars extends partially around the conductive material.

23. The apparatus of claim 21, wherein the respective electrode materials extend, at each of the layers of the first material in the stack of layers, between a first memory cell associated with a first pillar and a second memory cell associated with a second pillar, wherein the first pillar and the second pillar are separated by a pier.

24. The apparatus of claim 21, wherein the third material is separated from the first material at each of the layers of the first material in the stack of layers by the fourth material and a fifth material.

25. An apparatus, comprising:
a substrate;
a stack of layers formed by depositing alternating layers of a first material and a second material;
a plurality of piers extending through the stack of layers, wherein a portion of each pier comprises a third material, the plurality of piers formed by etching a plurality of first vertical cavities through the stack of materials and depositing a third material in at least a portion of each first vertical cavity;
a plurality of pillars extending through the stack of layers, wherein a set of pillars is positioned between respective piers of the plurality of piers, wherein the set of pillars between respective piers are separated from each other by the third material, and the third material is separated from the first material at each of the layers of the first material in the stack of layers by a fourth material, and wherein each set of pillars comprises a first bit line and a second bit line, the plurality of pillars formed by:
removing, at the layers of the first material and the layers of the second material, a portion of the third material and a portion of the liner from each column of the third material after replacing the first material with a fourth material at the layers of the first material, the fourth material being a conductive material, wherein the third material is recessed laterally at the layers of the first material and the layers of the second material after removing the portion of the liner from each column;
forming a first electrode liner in a portion of each recess of the third material after removing the portion of the third material and the liner from each column;
forming a fifth material in at least a portion of each recess of the third material after forming the first electrode liner in the portion of each recess of the third material; and
removing, at the layers having the fourth material, a portion of the first material and the liner from a portion of the first region and a portion of the second region after forming the fifth material in the at least the portion of each recess of the third material, wherein the layers having the fourth material comprise a plurality of second cavities after removing the portion of the first material and the liner from the portion of the first region and the portion of the second region; and
a first plurality of memory cells in contact with the first bit line, wherein respective memory cells of the first plurality of memory cells are in contact with the first material at each of the layers of the first material in the stack of layers via respective electrode materials that extend, at each of the layers of the first material in the stack of layers, at least partially around a respective pier; and
a second plurality of memory cells in contact with the second bit line, wherein respective memory cells of the second plurality of memory cells are in contact with the first material at each of the layers of the first material in the stack of layers via respective electrode materials that extend, at each of the layers of the first material in the stack of layers, at least partially around a respective pier.
